(19) United States
(12) Patent Application Publication
(10) Pub. No.: US 2025/0251472 A1
(43) Pub. Date: Aug. 7, 2025

(54) APPARATUS AND A METHOD

(71) Applicant: Nokia Technologies Oy, Espoo (FI)

(72) Inventors: Hongwei LI, Cambridge (GB); Zoran RADIVOJEVIC, Cambridge (GB); Charlie PATRICKSON, Exeter (GB); Efstratios DOUMANIS, Stuttgart (DE)

(21) Appl. No.: 19/042,696

(22) Filed: Jan. 31, 2025

(30) Foreign Application Priority Data
Feb. 2, 2024 (GB) 2401376.5

(51) Int. Cl. G01R 33/032

(52) U.S. Cl. CPC G01R 33/032

(57) ABSTRACT

An apparatus comprising: a resonant cavity configured for optical excitation of a material to which a magnetic field is applied, the material having at least one covalent structural defect; an electromagnetic feed configured to couple an input electromagnetic signal into the resonant cavity; an electromagnetic feed configured to couple an output electromagnetic signal from the resonant cavity; at least one processor; and at least one memory storing instructions that, when executed by the at least one processor, cause the apparatus at least to perform: controlling a variation in time of the applied magnetic field within the resonant cavity, and determine one or more features of the input electromagnetic signal based at least in part on a variation of the output electromagnetic signal with variation in time of the applied magnetic field.

### TECHNOLOGICAL FIELD

Examples of the disclosure relate to an apparatus and a method. Some relate to an apparatus and a method in measurement of signals.

### BACKGROUND

Quantum properties of electron spins of a material may be used in magnetic field sensing.

### BRIEF SUMMARY

According to various, but not necessarily all, examples there is provided an apparatus comprising: a resonant cavity configured for optical excitation of a material to which a magnetic field is applied, the material having at least one covalent structural defect; an electromagnetic feed configured to couple an input electromagnetic signal into the resonant cavity; means for coupling an output electromagnetic signal from the resonant cavity, comprising an electromagnetic feed; and means configured to control a variation in time of the applied magnetic field within the resonant cavity, and to determine one or more features of the input electromagnetic signal based at least in part on a variation of the output electromagnetic signal with variation in time of the applied magnetic field.

According to various, but not necessarily all, examples there is provided a method comprising: coupling an input electromagnetic signal into a resonant cavity; applying a magnetic field to a material having at least one covalent structural defect within the resonant cavity; optically exciting the material; controlling a variation in time of the applied magnetic field within the resonant cavity; coupling an output electromagnetic signal from the resonant cavity by an electromagnetic feed; and determining one or more features of the input electromagnetic signal based at least in part on a variation of the output electromagnetic signal with variation in time of the applied magnetic field.

According to various, but not necessarily all, examples there is provided examples as claimed in the appended claims.

The following portion of this ‘Brief Summary’ section, describes various features that may be features of any of the examples described in the foregoing portion of the ‘Brief Summary’ section. The description of a function should additionally be considered to also disclose any means suitable for performing that function.

In some, but not necessarily all, examples, the output electromagnetic signal has a frequency outside the range of visible light. In some, but not necessarily all, examples, the output electromagnetic signal does not comprise visible light.

In some but not necessarily all examples, the output electromagnetic signal is a microwave signal.

In some but not necessarily all examples, the resonant cavity comprises a dielectric material.

In some, but not necessarily all, examples, the apparatus comprises the material.

In some, but not necessarily all, examples, the apparatus comprises an optical excitation means for exciting the material.

In some, but not necessarily all, examples, the apparatus comprises means configured to apply the applied magnetic field within the resonant cavity.

In some, but not necessarily all, examples, the apparatus comprises means for coupling an output signal from the resonant cavity wherein the means for coupling an output signal from the resonant cavity are configured to detect light emitted by the material.

In some, but not necessarily all, examples, the means configured to control a variation in time of the applied magnetic field within the resonant cavity is configured to vary an applied magnetic flux density (B) in time.

In some, but not necessarily all, examples, the means configured to control a variation in time of the applied magnetic field within the resonant cavity is configured to vary a magnetic flux density (B) of a uniform applied magnetic field in time.

In some, but not necessarily all, examples, the means configured to couple an output electromagnetic signal from the resonant cavity is configured for measuring a transmitted electromagnetic signal.

In some, but not necessarily all, examples, the means configured to couple an output electromagnetic signal from the resonant cavity is configured for measuring a reflected electromagnetic signal.

In some, but not necessarily all, examples, the apparatus comprises means for controlling a frequency of the input electromagnetic signal before coupling into the resonant cavity.

In some, but not necessarily all, examples, the apparatus comprises means for controlling a frequency of a reference signal; and means for controlling a frequency of the input electromagnetic signal by mixing the input electromagnetic signal with the reference signal before coupling the input electromagnetic signal into the resonant cavity.

In some, but not necessarily all, examples, the means for controlling a frequency of the input electromagnetic signal are configured to produce the input electromagnetic signal as a pulse before coupling the pulsed input electromagnetic signal into the resonant cavity.

In some, but not necessarily all, examples, the apparatus comprises means for detecting a signal; and means for mixing the detected signal with the reference signal.

In some, but not necessarily all, examples, the determining means is configured to determine at least an amplitude of the input electromagnetic signal based on a change in amplitude of the output electromagnetic signal with variation in time of the applied magnetic field.

In some, but not necessarily all, examples, the determining means is configured to determine if resonance occurs based on the variation of the output electromagnetic signal and is configured to determine at least a frequency of the input electromagnetic signal based on the applied magnetic field when resonance occurs.

In some, but not necessarily all, examples, the determining means is configured to determine at least an amplitude of the input electromagnetic signal based on a change in phase of the output electromagnetic signal with variation in time of the applied magnetic field.

In some, but not necessarily all, examples, the apparatus comprises means configured to determine one or more features of the applied magnetic field, based at least in part on the output signal.

In some, but not necessarily all, examples, the apparatus comprises means for determining one or more features of the applied magnetic field, wherein said means are configured to detect changes in the output signal based on a variation of a frequency of the input electromagnetic signal.

In some, but not necessarily all, examples, the optical excitation means comprise a light source.

In some, but not necessarily all, examples, the excitation means comprise a laser or light emitting diode, LED.

In some, but not necessarily all, examples, the material comprises nitrogen vacancy center diamond.

In some, but not necessarily all, examples, the excitation means are configured to output light with a wavelength below or equal to 532 nm.

In some, but not necessarily all, examples, the resonant cavity is positioned within a shielding box, wherein the shielding box is configured to shield against microwaves and is not configured to shield against magnetic field.

In some, but not necessarily all, examples, a distance between the resonant cavity and the electromagnetic feed comprises a vertical component and a horizontal component, wherein the vertical component is dependent on a height of a spacer on which the resonator is positioned.

While the above examples of the disclosure and optional features are described separately, it is to be understood that their provision in all possible combinations and permutations is contained within the disclosure. It is to be understood that various examples of the disclosure can comprise any or all of the features described in respect of other examples of the disclosure, and vice versa. Also, it is to be appreciated that any one or more or all of the features, in any combination, may be implemented by/comprised in/performable by an apparatus, a method, and/or computer program instructions as desired, and as appropriate.

### BRIEF DESCRIPTION

Some examples will now be described with reference to the accompanying drawings in which:

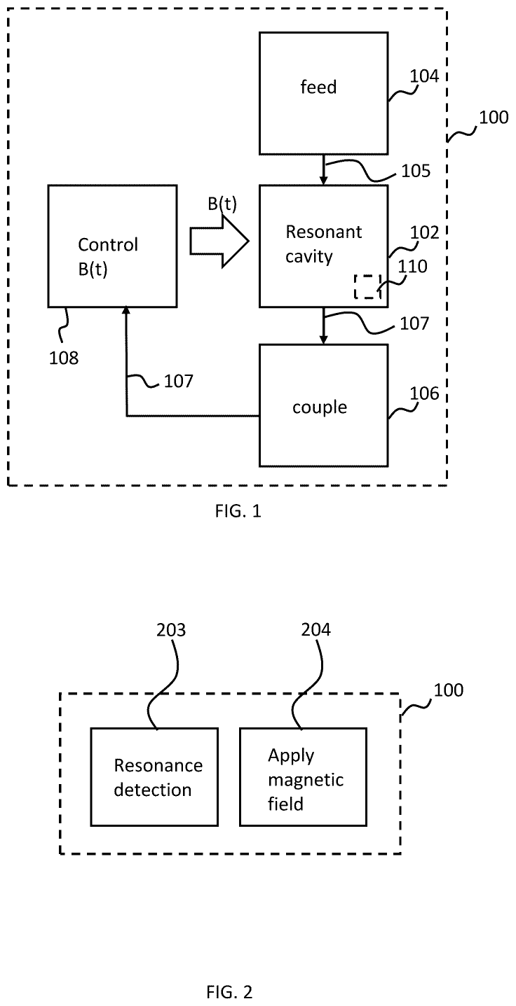

FIG. 1 shows an example of the subject matter described herein;

FIG. 2 shows another example of the subject matter described herein;

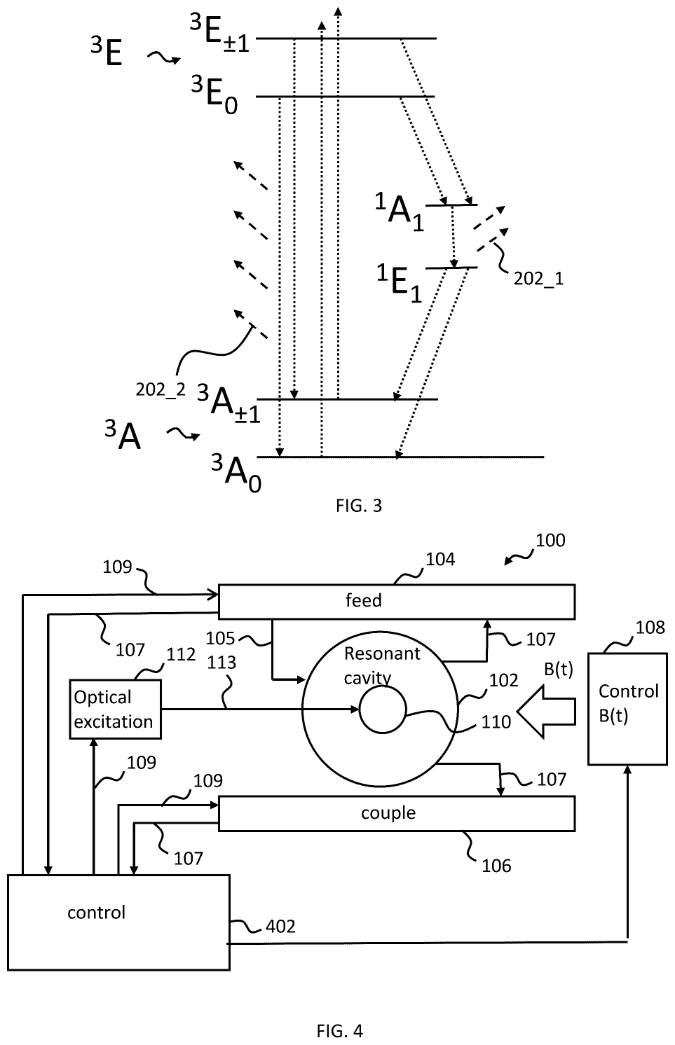

FIG. 3 shows another example of the subject matter described herein;

FIG. 4 shows another example of the subject matter described herein;

FIG. 5 shows another example of the subject matter described herein;

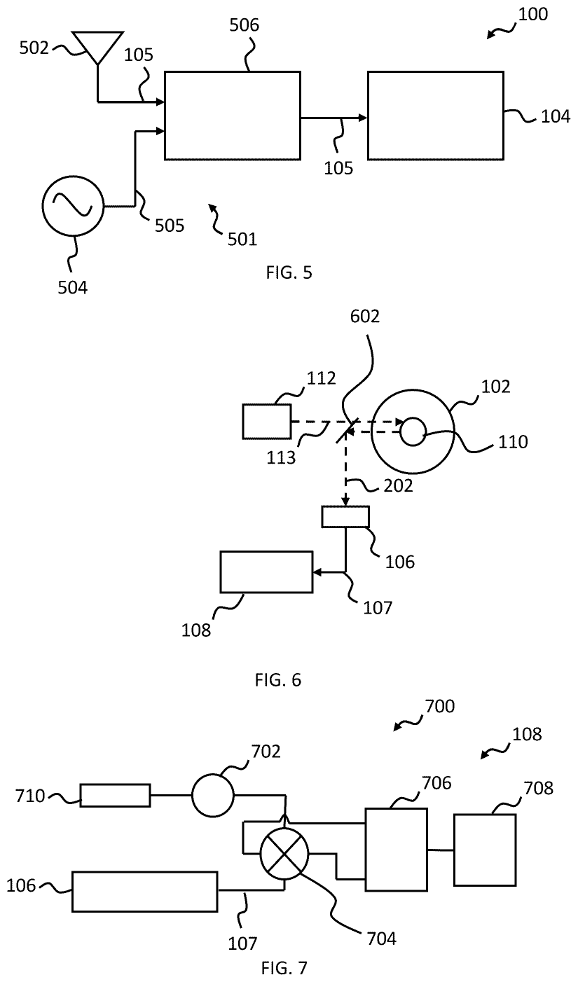

FIG. 6 shows another example of the subject matter described herein;

FIG. 7 shows another example of the subject matter described herein;

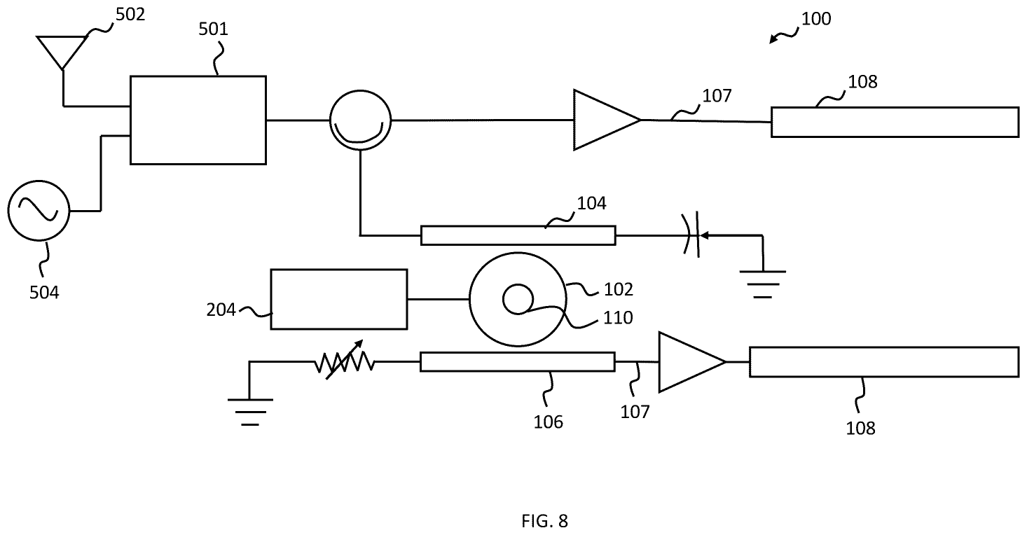

FIG. 8 shows another example of the subject matter described herein;

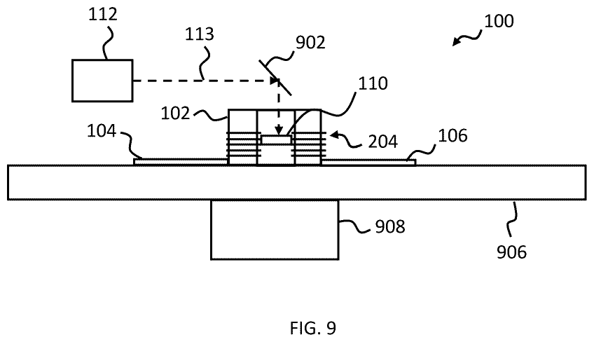

FIG. 9 shows another example of the subject matter described herein;

FIG. 10 shows another example of the subject matter described herein;

FIG. 11 shows another example of the subject matter described herein;

FIG. 12 shows another example of the subject matter described herein;

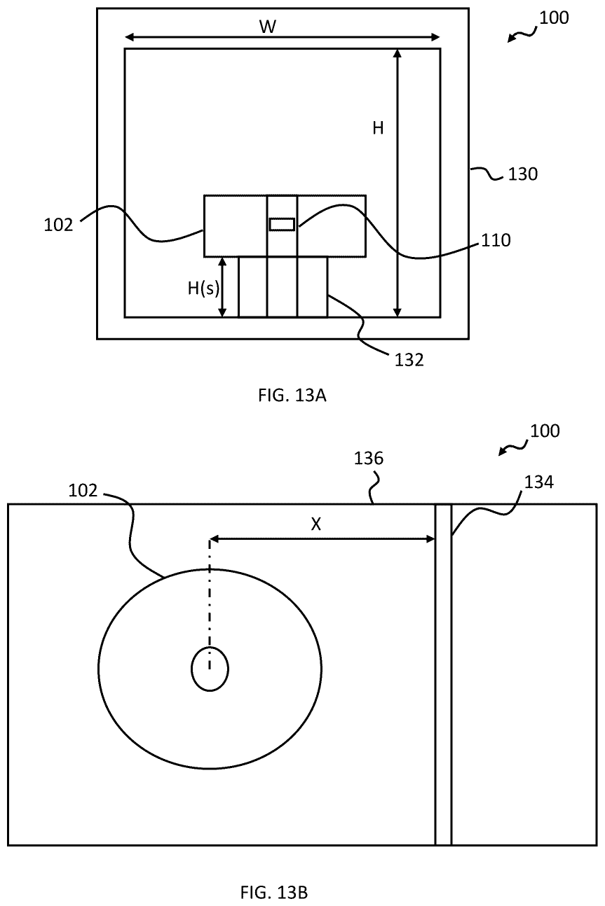

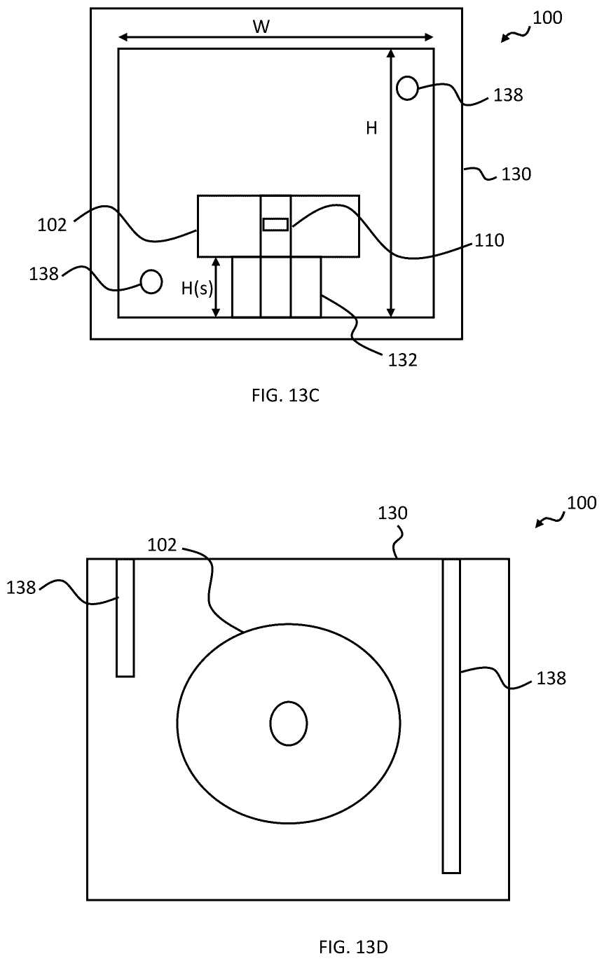

FIGS. 13A to 13D show another example of the subject matter described herein;

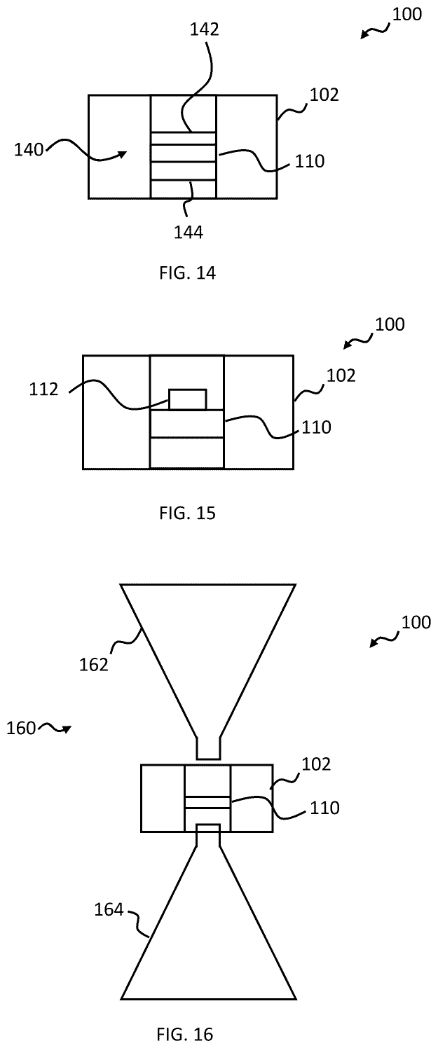

FIG. 14 shows another example of the subject matter described herein;

FIG. 15 shows another example of the subject matter described herein; and

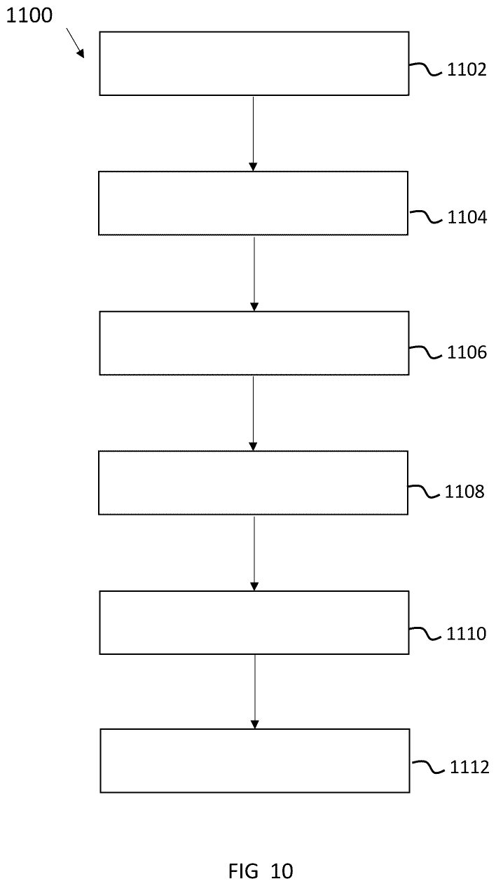

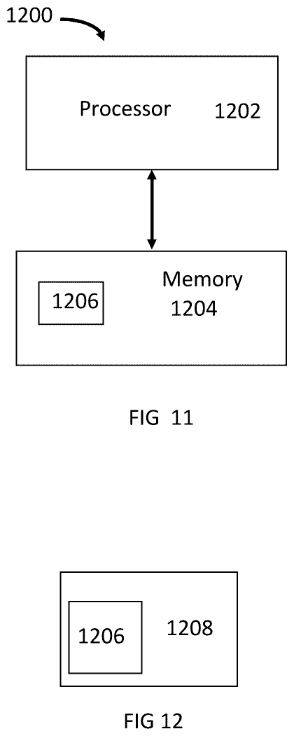

FIG. 16 shows another example of the subject matter described herein.

The figures are not necessarily to scale. Certain features and views of the figures can be shown schematically or exaggerated in scale in the interest of clarity and conciseness. For example, the dimensions of some elements in the figures can be exaggerated relative to other elements to aid explication. Similar reference numerals are used in the figures to designate similar features. For clarity, all reference numerals are not necessarily displayed in all figures.

### DETAILED DESCRIPTION

The following description and the enclosed FIGs relate to various examples of an apparatus 100 configured to determine one or more features of an input electromagnetic signal 105. The apparatus 100 comprises a resonant cavity 102 configured for optical excitation of a material 110 to which a magnetic field is applied, the material 110 having at least one covalent structural defect; an electromagnetic feed 104 configured to couple an input electromagnetic signal 105 into the resonant cavity 102; means 106 for coupling an output signal 107 from the resonant cavity 102; and means 108 configured to control a variation in time of the applied magnetic field B within the resonant cavity 102, and to determine one or more features of the input electromagnetic signal 105 based at least in part on a variation of the output signal 107 with variation in time of the applied magnetic field B.

FIG. 1 schematically illustrates an example of an apparatus 100. FIG. 2 schematically illustrates features of the apparatus 100. At least some features of the apparatus 100 not illustrated in FIG. 1 are illustrated in FIG. 2.

The resonant cavity 102 is configured for optical excitation of a material 110 having at least one covalent structural defect (hereafter “the material”).

FIG. 3 illustrates possible spin states of electrons within the material 110 (hereafter “the electrons”) and possible transitions between said spin states. In FIG. 3, spin states are illustrated using solid horizontal lines; transitions between spin states are illustrated using dotted lines between the solid horizontal lines; and light is illustrated using dashed lines.

At or close to room temperature, and without external excitation, the electrons are in a ground state (³A). Electrons in the ground state have ground spin states ³A₀ or ³A_{±1}.

Excitation of the material 110 causes excitation of the electrons across the electron energy gap to the excited state (³E). Electrons in the excited state have excited spin states ³E₀ or ³E_{±1}.

Excitation of the material 110 may be caused by applying an external electromagnetic field to the material 110, for example by applying laser light to the material 110. The excitation will push electron spin states to qubit ground state |0> (³A₀) due to un-balanced non-luminescent decay route through states ¹A₁ and ¹E₁.

Application of a magnetic field B across the material 110 causes a split of the states ³A₊₁ and ³A₋₁ to different energy levels. This causes a change in the energy difference between qubit ground state |0> (this is ³A₀ state) and qubit excited state |1> (this can be either ³A₊₁ or ³A₋₁ state, depending on experimental requirement).

The energy differences between the discrete energy levels 0 and ±1 are determined by the Zeeman effect and/or by material parameters of the material 110: the strain (which is sample-dependent) and the zero-field splitting (which is defect-specific, and taken to be constant at approximately 2.87 GHz at room temperature).

The Zeeman effect describes the change in energy of a spin state under an applied DC magnetic field. The energy difference between |0> and |1> is proportional to the intensity of the applied magnetic field. Therefore, variation of the magnetic field applied across the material 110 causes variation in the energy difference between |0> and |1> states. It is therefore possible to detect DC magnetic fields by changes in the energy difference and/or by changes in electron spin resonance transition energy, for example changes in electron spin resonance transition energy away from 2.87 GHz.

An electromagnetic field resonant frequency between the electron spin qubit states |0> and |1> is proportional to the energy difference between them. Therefore, variation of the magnetic field applied across the material 110 changes the resonant frequency of the electron spin qubit sates and may be used to tune the material.

An electromagnetic feed 104 is configured to couple an input electromagnetic signal 105 into the resonant cavity 102 housing the material 110. The input electromagnetic signal 105 interacts with the electrons. A portion of the electrons absorb energy from the input electromagnetic signal 105. Absorption of energy from the input electromagnetic signal 105 causes changes in an output signal 107 coupled from the resonant cavity 102. Resonance occurs between the input electromagnetic signal 105 and the electron spin qubit states when the frequency of the input electromagnetic signal 105 is equal to the resonant frequency of the electron spin qubit states.

In some, but not necessarily all, examples, the resonant cavity (also referred to herein as the resonator) comprises a dielectric material. In some such examples, the spin ensemble captured in the material 110, for example diamond with nitrogen vacancy centers, is coupled to the dielectric resonant cavity via a shared resonance.

The strength of the spin-dielectric resonator coupling can be described by the cooperativity, ξ:

$$ξ = \frac{4 {g}_{{eff}^{2}}}{{κ}_{S} {κ}_{DR}}$$

Where:
κₛ is the electron spin transition linewidth, described by

$$\frac{1}{{T}_{2}^{*}} ;$$

T₂* is the inhomogeneous broadening;
κ_{DR} is the dielectric resonator linewidth;
g_{eff} is the effective spin-dielectric resonator coupling, which is proportional to

$$\frac{1}{{v}_{Cav}} ;$$

and
V_{Cav} is the mode volume of the dielectric resonator.

The linewidths of the electron spin and dielectric resonator resonances affect the sensitivity and performance of the apparatus when used as a sensor.

In some, but not necessarily all, examples, the apparatus is designed to match the dielectric resonator linewidth with the spin linewidth. In other examples, the apparatus is designed to minimize the dielectric resonator linewidth. The dielectric resonator linewidth is usually larger than the spin linewidth.

This can maximize the sensitivity as for a defined change in DC magnetic field, a sharper coupled linewidth will produce a larger phase shift in the reflected microwave as the microwave field observes a larger shift in resonance frequency due to the steeper slope of the resonance.

The linewidth of the dielectric resonator can be described by the quality factor Q:

$$Q = \frac{ω}{{κ}_{D R}}$$

Where ω is the frequency of the dielectric resonator.

Sensitive detection of the output electromagnetic signal and of the applied magnetic field can be provided by maximizing the strength of g_{eff}.

In some, but not necessarily all, examples, resonance occurs at approximately 2.87 GHz. For the spin ensemble, this corresponds to the electron spin resonance transition between two spin states in which Δms=1; for example, in diamond with nitrogen vacancy centers, the electron spin resonance transition between the ms=0 and ms=+1 states, or between the ms=0 or ms=−1 states. For the resonator, this corresponds to the TE₀₁ (transverse electromagnetic) mode of the resonator.

Variation of the magnetic field B can be used to tune the system to resonance by varying the resonant frequency of the electrons to match the frequency of the input electromagnetic signal 105. For example, a local change in DC magnetic field will produce a change in the electron spin resonance transition energy through the Zeeman effect. When the spin-dielectric resonator system is coupled, changes in the resonant frequency of the electrons cause corresponding changes in the resonance of the dielectric resonator.

At resonance, coherent energy transfer between the electromagnetic field and the system occurs, causing oscillation of the system between energy states.

The material is initiated to the ground state by application of the excitation means. Then, when resonance occurs between the input electromagnetic signal and the qubit states, electron spins oscillate between the ground state |0> and the excited state |1>.

The system thus oscillates between the ground state and the excited state and therefore the occupation expectation levels of the states oscillate.

The resonant frequency of the resonant cavity and the electron quantum spin states (bare states) couple together and form dressed states. This coupling causes a shift in resonance with the input electromagnetic signal (dispersive effect). For quantum ground state |0> and excited state |1>, the shift of resonance will be in the opposite directions to the original cavity resonant frequency.

Therefore, at or near resonance, changes in the output signal 107 coupled from the resonant cavity 102 occur.

Features of an input electromagnetic signal 105 may be determined by coupling the input electromagnetic signal 105 into the resonant cavity 102 in which the material 110 is placed and varying the applied magnetic field B until resonance between the input electromagnetic signal 105 and the electron spin qubit states occurs.

Features of the input electromagnetic signal 105 may be determined in dependence upon the changes in the output signal 107, for example an output electromagnetic signal, which occur at or near resonance.

In the initialization process to quantum spin ground state |0> at the beginning or during the measurement, the orbit states of the excited electrons decay from the excited state (³E) to the ground state (³A) in one of two ways.

In a first decay process, the energy states of the excited electrons decay directly from the excited state to the ground state. Such decay causes light having a first wavelength 202_2 to be emitted from the material 110. The spin states of the electrons are conserved.

In a second decay process, the energy states of the excited electrons decay from the excited state to the ground state via one or more intermediate singlet states ¹A₁, ¹E₁. Decay from a first intermediate state to a second intermediate state causes light having a second wavelength 202_1 to be emitted from the material 110. The spin states of the electrons are not conserved.

More electrons with state ³E_{±1} go through the second decay process than those with state ³E₀. Thus, with time and oscillation between excited states and ground states, all electrons move to the |0> spin state (ground state).

Once all the electrons are in ground state |0>, the input electromagnetic signal may be used to tune the distribution between |0> and |1>.

The population of electrons in |1> and |0> states determines the emission strength of the emitted light 202_1 and 202_2. Under constant excitation, all electrons are in the |0> state and the emitted light 202_1 and 202_2 1 is constant. Under resonant electromagnetic field, more electrons are pumped to |1> states, and therefore more electrons go through 1A state for decay. In this case, emitted light 202_2 will become weaker and emitted light 202_1 will become stronger. Determination of that resonance is occurring can be made based on measured changes in emitted light 202_2 and 202_1.

Therefore, at or near resonance, changes in light 202 emitted by the decay of the energy states of the excited electrons occur.

Features of the input electromagnetic signal 105 may be determined in dependence upon the change in the light 202 emitted by the decay of the energy states of the excited electrons which occurs at or near resonance.

Features of a magnetic field applied across the resonant cavity 102 may be determined by coupling an input electromagnetic signal 105 having a controllable frequency into the resonant cavity 102 in which the material 110 is placed. The controllable frequency is varied based on an expected resonant frequency of the electron spin qubit states.

In some, but not necessarily all, examples, the apparatus is configured to probe the resonant energy of the coupled system, which is amplified by the dielectric resonator, to learn information about the DC magnetic field. This may be performed by applying a microwave field at the “bare” (uncoupled) dielectric resonator resonance. If the frequency of this resonance shifts under a DC magnetic field, the reflected microwave field will undergo a phase shift proportional to the shift in the resonant frequency. The apparatus may record the amplitude of this phase shift to quantify the DC magnetic field.

Changes in the applied magnetic field B cause changes in the resonant frequency of the electron spin qubit states. Therefore, changes in the applied magnetic field B may cause resonance to occur or to stop between the input electromagnetic signal 105 and the electron spin states. Occurrence or ceasing of resonance between the input electromagnetic signal 105 and the electrons causes changes in the output signal 107.

Thus, changes in the applied magnetic field B cause changes in an output signal 107 coupled from the resonant cavity 102. For example, changes in the applied magnetic field B cause changes in an output electromagnetic signal coupled from the resonant cavity 102 and changes in light emitted by the decay of the energy states of the excited electrons.

Features of the applied magnetic field B may be determined in dependence upon the changes in the output electromagnetic signal and/or changes in the light emitted by the decay of the energy states of the excited electrons.

The sensing process performed by the apparatus can be summarized by the following sequence:
1) Tune quantum spin states to be in resonant with cavity to form polariton states (or dressed states in not in full resonance)
2) Initialize quantum spins to ground state |0>
3) Couple in electromagnetic signal to be sensed (this can be mixed with reference signal) and this signal will excite some quantum states from |0> to |1>
4) Couple in readout electromagnetic signal with wider frequency range to cover the whole resonant range of the cavity (this can be a frequency sweep, or a wideband signal covers all frequencies).
5) Above step 3) and 4) can be mixed as well in some instances.
6) Measure reflected or transmitted signal for dispersion peaks changes. The measured changes in dispersion peaks for |0> and |1> states are used to determine the properties of original electromagnetic signals to be sensed.

FIG. 4 illustrates an example system comprising the apparatus 100. In the example of FIG. 4, control means 402 provides the means 108 configured to control a variation in time of the applied magnetic field B within the resonant cavity 102, and to determine one or more features of the input electromagnetic signal 105 based at least in part on a variation of the output signal 107 with variation in time of the applied magnetic field B.

Control means 402 further provides one or more control signals 109 to:
the electromagnetic feed 104 configured to couple an input electromagnetic signal 105 into the resonant cavity 102;
the means 106 for coupling an output signal 107 from the resonant cavity 102;
the means 108 configured to control a variation in time of the applied magnetic field B within the resonant cavity 102; and
an optical excitation means 112.

In examples, such as the example illustrated in FIG. 2, the apparatus 100 comprises means 203 for determining that resonance is occurring between the electrons and the input electromagnetic signal 105. The means 203 for determining that resonance is occurring between the electrons and the input electromagnetic signal 105 are configured to detect resonance based at least in part on a variation of the output signal 107.

Variations in the output signal 107 may comprise at least one of: a change in amplitude; a change in phase; a change in frequency; a change in light intensity.

Detecting resonance may comprise determining that the variation of the output signal 107 occurs with variation of the magnetic field.

The material 110 is provided within a resonant cavity 102. An input electromagnetic signal 105 is coupled into the resonant cavity 102 and an output signal 107 is coupled from the resonant cavity 102. A variable magnetic field is applied across the resonant cavity 102.

Coupling the material 110 to the resonant cavity 102 enables interactions to occur simultaneously between the electrons of the material 110 and the input electromagnetic signal 105 and between the resonant cavity 102 and the input electromagnetic signal 105. The simultaneous interaction enables a different output signal 107 to be coupled from the resonant cavity 102 than if only resonance between the electrons of the material 110 and the input electromagnetic signal 105 occurs. The different output signal 107 facilitates determination of one or more features of the input electrical signal that is based on the output signal 107.

The coupling between the material 110 and the resonant cavity 102 is affected by coupling parameters such as a frequency of the input electromagnetic signal 105; an amplitude of the input electromagnetic signal 105; and the applied magnetic field B. Thus, changes in one or more of the coupling parameters cause changes in the output signal 107. Features of the input electromagnetic signal 105 and/or the applied magnetic field B may be determined based on the changes in the output signal 107.

In examples, the resonant cavity comprises a dielectric material. In some such examples, the resonant cavity comprises a high dielectric constant material. In some such examples, the dielectric material comprises ceramic.

In some, but not necessarily all, examples, the resonant cavity is formed by an external wall or walls made of a dielectric material surrounding the resonant cavity.

In examples, the resonant cavity 102 has a cylindrical shape. In some such examples, the resonant cavity 102 has a hollow cylinder shape. In other examples, the resonant cavity 102 does not have a cylindrical shape.

In examples, the shape of the resonant cavity 102 is such that efficiency of coupling the input electromagnetic signal 105 into the resonant cavity 102 and/or the efficiency of coupling the output electromagnetic signal 107 out of the resonant cavity 102 is maximized.

In examples, the resonant cavity comprises an inner wall and an outer wall. In some, but not necessarily all, examples, at least one of the inner wall or the outer wall is formed from a dielectric material. The inner wall and the outer wall are nested such that the inner wall is at least partially encompassed by the outer wall. In examples in which the resonant cavity 102 has a cylindrical shape, the inner wall and the outer wall are nested circles; in examples, the inner wall and the outer wall are concentric circles. The resonant frequency of the resonant cavity may be changed by changing the relative positions of the inner wall and the outer wall.

In examples, the resonant cavity 102 has a size determined by at least one of a required resonant frequency or a required Q factor at resonance.

In examples, the resonant cavity 102 has one or more dimensions determined by at least one of the required resonant frequency or the required Q factor associated with the resonant frequency. For example, one or more of an outside diameter of the resonant cavity 102; an inside diameter of the resonant cavity 102; or a height of the resonant cavity 102 has a fixed value and/or one or more of the outside diameter; the inside diameter; or the height has a variable, controlled value that is dependent on at least one of the required resonant frequency or the required Q factor.

In examples, the required resonant frequency is determined based on an expected and/or a controlled frequency of the input electromagnetic signal 105.

In examples, the required resonant frequency is in the range 260 MHz-260 GHz.

In examples, the required Q factor is determined based on a sensitivity requirement of the apparatus. The dispersive shift is proportional to the Q value. A higher Q value provides a system with higher sensitivity and reduced bandwidth, Thus, in examples, the required Q factor is based on a cost function of a combination of sensitivity and bandwidth.

In examples, the required Q factor is in the range 30,000-300,000.

The material 110 is coupled to the resonant cavity 102 such that an input electromagnetic signal 105 coupled to the resonant cavity 102 is coupled to the material 110 within the resonant cavity 102, and the material 110 is positioned within the resonant cavity 102 such that a magnetic field applied across the resonant cavity 102 is applied to the material 110 within the resonant cavity 102. In some, but not necessarily all examples, the apparatus 100 comprises the material 110.

The material 110 comprises at least one covalent structural defect. The covalent structural defect causes the electrons to have quantum spin states that can be changed at room temperature by one or more stimuli. Example stimuli include a magnetic field; an electric field; or electromagnetic radiation, such as microwaves, radio waves or visible light.

In examples, the material 110 comprises a giant covalent structure material 110 having at least one covalent structural defect, such as diamond having at least one covalent structural defect or silicon carbide having at least one covalent structural defect.

In examples, the at least one covalent structural defect comprises at least one color center defect, for example: nitrogen vacancy, group IV color centers, such as, for example, silicon vacancy, germanium vacancy, tin vacancy or lead vacancy; or a divacancy center.

In examples, the material 110 comprises nitrogen vacancy center in diamond. In some such examples, the optical excitation means 112 are configured to output light with a wavelength not larger than 532 nm.

A magnetic field is applied to the resonant cavity 102 and thus to the material 110 within the resonant cavity 102. In some, but not necessarily all examples, such as the example illustrated in FIG. 2, the apparatus 100 comprises means 204 configured to apply the applied magnetic field B within the resonant cavity 102.

In examples, the means 204 configured to apply the applied magnetic field B within the resonant cavity 102 comprise a coil. In some such examples, the coil is positioned near to the resonant cavity 102 such that the resonant cavity 102 is positioned within a magnetic field generated by the coil. In other such examples, the coil is positioned around the resonant cavity 102.

In examples, the means 204 configured to apply the applied magnetic field B within the resonant cavity 102 comprise one or more magnets. The magnets may be permanent magnets. In some such examples, the applied magnetic field B is applied by the one or more magnets. Variation of the applied magnetic field B is controlled by varying a position and/or an orientation of one or more of the one or more magnets.

As illustrated in FIG. 1, the apparatus 100 comprises means 108 configured to control a variation in time of the applied magnetic field B within the resonant cavity 102. The applied magnetic field B across the material 110 may thus be varied in time.

In examples, the means 108 configured to control a variation in time of the applied magnetic field B within the resonant cavity 102 are configured to vary the magnetic flux density of the applied magnetic field B in time.

In examples, the applied magnetic field B flux density is uniform or substantially uniform within the resonant cavity 102. In such examples, the means 108 configured to control a variation in time of the applied magnetic field B within the resonant cavity 102 are configured to vary a magnetic flux density of the uniform applied magnetic field B in time.

The resonant frequency of the electron spin qubit states is proportional to the flux density of the applied magnetic field B; thus, varying the applied magnetic field B with time causes the resonant frequency of the electron spin qubit states to vary with time. Varying the applied magnetic field B with time therefore varies the frequency at which resonance may occur between the electrons and an input electromagnetic signal 105.

In examples, the means 108 configured to control a variation in time of the applied magnetic field B are configured to vary the applied magnetic field B such that the electron spin qubit states have a resonant frequency matching the frequency of the input electromagnetic signal 105, causing resonance between the input electromagnetic signal 105 and the spin states of electrons.

In examples, such as examples in which the frequency of the input electromagnetic signal 105 is controlled, the variation in time of the applied magnetic field B is dependent upon the frequency of the input electromagnetic signal 105. The means 108 are configured to vary the applied magnetic field B such that the resonant frequency matches the controlled frequency of the input electromagnetic signal 105.

In examples, such as examples in which the frequency of the input electromagnetic signal 105 is not known, the means are configured to vary the applied magnetic field B until resonance is detected.

The resonant cavity 102 is configured for optical excitation of the material 110. In examples, the optical excitation of the material 110 is caused by optical excitation means 112. In some, but not necessarily all examples, the apparatus 100 comprises the optical excitation means 112.

In examples, the optical excitation means 112 comprise a light source, for example a laser or light emitting diode (LED). In such examples, the optical excitation means 112 is configured to emit light.

In examples, the apparatus 100 comprises optics 902 configured to provide light 113 output by the optical excitation means 112 to the material 110.

The apparatus 100 comprises an electromagnetic feed 104 configured to couple an input electromagnetic signal 105 into the resonant cavity 102. In examples, the electromagnetic feed 104 comprises a microstrip waveguide.

In some, but not necessarily all, examples, the input electromagnetic signal has a frequency outside the range of visible light.

In some, but not necessarily all, examples, the input electromagnetic signal is a microwave signal.

In examples such as the example illustrated in FIG. 5, the apparatus 100 comprises means 502 configured to receive the input electromagnetic signal 105. In some such examples, the means 502 configured to receive the input electromagnetic signal 105 comprise at least one antenna 502 configured to receive radio signals.

In some, but not necessarily all, examples, the input electromagnetic signal 105 comprises a detected signal 105. The input electromagnetic signal 105 may be mixed with the detected signal or the input electromagnetic signal 105 may be the detected signal.

In examples, the apparatus 100 comprises means 501 for controlling a frequency of the input electromagnetic signal 105 before coupling the input electromagnetic signal 105 into the resonant cavity 102.

FIG. 5 illustrates an example in which the means for controlling a frequency of the input electromagnetic signal 105 comprise means 504 for controlling a frequency of a reference signal 505. In examples, the means for controlling a frequency of the reference signal comprise means for generating the reference, for example a tunable signal source. The reference signal may comprise a local oscillator signal.

In examples, such as the example of FIG. 5, the means for controlling a frequency of the input electromagnetic signal 105 comprise means 506 for mixing the input electromagnetic signal 105 with the reference signal before coupling the mixed input electromagnetic signal 105 into the resonant cavity 102 via the electromagnetic feed 104. In examples, the mixed input electromagnetic signal 105 is filtered before being coupled into the resonant cavity 102 via the electromagnetic feed 104.

By mixing the input electromagnetic signal 105 with the reference signal 505, at least one of a frequency or an amplitude of the input electromagnetic signal 105 may be controlled.

In some such examples, the means 501 for controlling a frequency of the input electromagnetic signal 105 are configured to produce the input electromagnetic signal 105 as a pulse before coupling the pulsed input electromagnetic signal 105 into the resonant cavity 102.

In some examples in which the applied magnetic field B is not fixed, the means 501 for controlling a frequency of the input electromagnetic signal 105 are configured to vary the frequency of the input electromagnetic signal 105 such that resonance between the input electromagnetic signal 105 and the electrons occurs.

As illustrated in FIG. 1, the apparatus 100 comprises means 106 for coupling an output signal 107 from the resonant cavity 102.

In examples, the means 106 for coupling an output signal 107 from the resonant cavity 102 are configured to perform at least one of coupling an output electromagnetic signal from the resonant cavity 102 or detecting light emitted by the material 110.

In examples, the means 106 for coupling an output signal 107 from the resonant cavity 102 are configured to provide the output signal 107 to the means 108 configured to determine one or more features of the input electromagnetic signal 105.

In examples, the output signal 107 comprises an output electromagnetic signal. In some such examples, the means 106 configured for coupling an output signal 107 from the resonant cavity 102 comprise an electromagnetic feed.

In some, but not necessarily all, examples, the output electromagnetic signal has a frequency outside the range of visible light. In some, but not necessarily all, examples, the output electromagnetic signal is a microwave signal.

In examples, the means 106 configured for coupling an output electromagnetic signal from the resonant cavity 102 are configured to detect a variation in the output electromagnetic signal 107 with variation in time of the applied magnetic field B. In some such examples, the means 108 are configured to detect a variation in the output electromagnetic signal 107 when interaction between the cavity-electron spins system and the input electromagnetic signal 105 is determined.

In examples, the means 106 configured for coupling an output signal 107 from the resonant cavity 102 are configured to measure the output electromagnetic signal 107 when interaction occurs between the input electromagnetic signal 105 and the cavity-electron spins system.

In examples, the means 106 configured for coupling an output signal 107 from the resonant cavity 102 are configured to measure the output electromagnetic signal 107 near resonance between the input electromagnetic signal 105 and the cavity-electron spins system.

In examples, the means 106 configured for coupling an output signal 107 from the resonant cavity 102 are configured to measure a transmitted electromagnetic signal. Measuring the transmitted electromagnetic signal comprises measuring at least one of: a forward voltage gain; or an insertion loss.

An increase in energy absorption by the cavity-electron spins system at or near resonance causes a change in transmission of energy and thus a change in an amplitude of the transmitted electromagnetic signal.

An increase in dispersive interaction with the electron spin qubit states at or near resonance causes a shift in transmission of energy and thus a change in a frequency or an amplitude or a phase of the transmitted electromagnetic signal.

In examples, the means 106 configured for coupling an output signal 107 from the resonant cavity 102 are configured to measure a reflected electromagnetic signal. Measuring the reflected electromagnetic signal comprises measuring at least one of: an input port reflection coefficient; an input return loss; or a voltage standing wave ratio.

An increase in energy absorption by the cavity-electron spins system at or near resonance causes a decrease in reflection of energy and thus a decrease in an amplitude of the reflected electromagnetic signal.

An increase in dispersive interaction with the cavity-electron spins system at or near resonance causes a shift in reflection of energy and thus a change in a frequency or an amplitude or a phase of the transmitted electromagnetic signal.

In some, but not necessarily all examples, the means 106 configured for coupling an output signal 107 from the resonant cavity 102 are configured to measure a transmitted electromagnetic signal and a reflected electromagnetic signal.

An increase in dispersion interaction by the cavity-electron spins system at or near resonance causes a change in phase of the output electromagnetic signal.

In examples, the means configured for coupling an output signal 107 from the resonant cavity 102 are configured to provide an output signal 107 to the means 108 configured to determine one or more features of the input electromagnetic signal 105 based at least in part on a variation of the output signal 107 with variation in time of the applied magnetic field B.

In some examples, such as the example illustrated in FIG. 6, the output signal 107 comprises light. In such examples, the means configured for coupling an output signal 107 from the resonant cavity 102 comprise a light detector. In some, but not necessarily all, examples, the means configured for coupling an output signal 107 from the resonant cavity comprise means for coupling an output signal comprising visible light and means for coupling an output electromagnetic signal that does not comprise visible light.

In examples, the apparatus comprises optics 602 configured to provide the light output by the material 110 to the means 106 configured for coupling an output signal 107 from the resonant cavity 102.

In examples, the means 106 configured for coupling an output electromagnetic signal from the resonant cavity 102 are configured to detect a variation in the light output by the material 110 with variation in time of the applied magnetic field B. In some such examples, the means are configured to detect a variation in the light output by the material 110 when resonance between the electrons and the input electromagnetic signal 105 is determined.

In examples, the means 106 configured for coupling an output signal 107 from the resonant cavity 102 are configured to measure at least one feature of the light 202 output by the material 110. The at least one feature may comprise any one or more of: intensity; wavelength; intensity over time.

The means 106 configured for detecting light emitted by the material 110 are configured to provide an output signal 107 to the means 108 configured to determine one or more features of the input electromagnetic signal 105 based at least in part on a variation of the output signal 107 with variation in time of the applied magnetic field B.

In examples, the apparatus 100 comprises means 108 configured to determine one or more features of the input electromagnetic signal 105 based at least in part on a variation of the output signal 107 with variation in time of the applied magnetic field B.

In examples, determination of one or more features of the input electromagnetic signal 105 is carried out in dependence upon a determination that resonance is occurring between the cavity-electron spins system and the input electromagnetic signal 105.

In examples, the apparatus 100 comprises means 108 configured to determine one or more features of the input electromagnetic signal 105 based at least in part on a variation of the output electromagnetic signal with variation in time of the applied magnetic field B.

In examples, the means 108 configured to determine one or more features of the input electromagnetic signal 105 comprise signal detection circuitry, for example heterodyne signal detection circuitry.

FIG. 7 schematically illustrates example circuitry 700 configured to determine one or more features of the input electromagnetic signal 105. In the example of FIG. 7, the circuitry comprises: the means 106 for coupling an output signal 107 from the resonant cavity 102; a tunable signal source 710; a phase shifter 702 for phase control of a signal generated by the tunable output source 710; an in-phase and quadrature mixer 704 configured to mix the output signal 107 and the signal generated by the tunable signal source 710; an analog to digital converter 706; and a microcontroller 708.

In examples, the determining means 108 is configured to determine at least one of an amplitude or a frequency of the input electromagnetic signal 105.

In examples, determination of the amplitude of the input electromagnetic signal 105 is based on a change in amplitude of the output electromagnetic signal 107 with variation in time of the applied magnetic field B.

The amplitude of the input electromagnetic signal 105 is proportional to a change in amplitude of the output electromagnetic signal 107 with variation in time of the applied magnetic field B.

In examples, the amplitude of the input electromagnetic signal 105 is proportional to a change in amplitude of the output electromagnetic signal 107 when resonance occurs between the electrons and the input electromagnetic signal 105. The change in amplitude is relative to the amplitude of the output electromagnetic signal when resonance does not occur between the electrons and the input electromagnetic signal 105.

The amplitude of the input electromagnetic signal 105 is proportional to a change in amplitude of a reflected electromagnetic signal. The amplitude of the input electromagnetic signal 105 is proportional to a change in amplitude of a transmitted electromagnetic signal.

In examples, determination of the amplitude of the input electromagnetic signal 105 is based on a change in phase of the output electromagnetic signal with variation in time of the applied magnetic field B.

In examples, determination of the frequency of the input electromagnetic signal 105 is based on a change in frequency of the output electromagnetic signal with variation in time of the applied magnetic field B.

In examples, determination of the frequency of the input electromagnetic signal 105 is based on the applied magnetic field B when resonance occurs.

In examples, such as the example illustrated in FIG. 1, the apparatus 100 comprises means 108 configured to determine one or more features of the input electromagnetic signal 105 based at least in part on a variation of the light emitted by the electrons with variation in time of the applied magnetic field B.

In examples the determining means 108 is configured to determine at least one of an amplitude or a frequency of the input electromagnetic signal 105.

In examples, determination of the amplitude of the input electromagnetic signal 105 is based on a change in intensity of the output light 202.

In examples, the apparatus 100 comprises means 108 configured to determine one or more features of the applied magnetic field B, based at least in part on the output signal 107.

In examples, a magnetic field having a first magnetic flux density is applied across the resonant cavity 102 and an input electromagnetic signal 105 having a controlled frequency is coupled into the resonant cavity 102. The frequency of the input electromagnetic signal 105 is controlled such that resonance occurs between the cavity-electron spins system and the input electromagnetic signal 105 when the photon energy of the input electromagnetic signal is the same as the energy difference between qubit states |0> and |1>.

A change in the magnetic field causes the energy difference between qubit states |0> and |1> to change which in turn causes the system to move away from resonance. Changes in the output signal 107 are thus caused.

Features of the magnetic field can be determined based on the changes in the output signal 107.

In examples, the means for determining one or more features of the applied magnetic field B are configured to detect changes in the output signal 107 based on a variation of a frequency of the input electromagnetic signal 105.

The magnetic field is applied across the resonant cavity 102 and an input electromagnetic signal 105 having a controllable frequency coupled into the resonant cavity 102. The frequency of the input electromagnetic signal 105 is varied until resonance occurs between the electrons and the input electromagnetic signal 105. The resonance causes a change in the output signal 107.

The magnetic flux density may thus be determined in dependence on the frequency of the output electromagnetic signal 107 when resonance occurs between the electrons and the input electromagnetic signal 105.

In examples, the apparatus 100 comprises control means 402. The control means 402 may be configured to provide one or more control signals 109.

One or more of the one or more control signals 109 may be provided to any of: the electromagnetic feed 104 configured to couple an input electromagnetic signal 105 into the resonant cavity 102; the means 106 for coupling an output signal 107 from the resonant cavity 102; or the optical excitation means 112.

FIG. 8 illustrates a schematic view of an example apparatus 100. Features illustrated in FIG. 8 may be provided in the combination illustrated by FIG. 8 or in other combinations. It will be appreciated that not all features illustrated in FIG. 8 are essential.

The apparatus comprises the electromagnetic feed 104 configured to couple the input electromagnetic signal 105 into the resonant cavity and means 106 for coupling an output signal 107 from the resonant cavity 102, configured for measuring a transmitted electromagnetic signal. In the example of FIG. 8, the electromagnetic feed 104 provides an additional means for coupling an output signal 107 from the resonant cavity 102, configured for measuring a reflected electromagnetic signal.

In some such examples, the apparatus is configured to simultaneously measure a reflected electromagnetic signal and a transmitted electromagnetic signal.

In some, but not necessarily all, examples, the electromagnetic feed 104 configured to couple an input electromagnetic signal 105 into the resonant cavity 102 and the means 106 for coupling an output signal 107 from the resonant cavity 102 comprise microstrip couplers.

In examples, the output signal 107 is processed before being provided to the means 108 configured to determine one or more features of the input electromagnetic signal 105 based at least in part on a variation of the output signal 107 with variation in time of the applied magnetic field B. In the example of FIG. 8, processing the output signal 107 comprises passing the output signal 107 through a low noise amplifier.

FIG. 9 illustrates a side view of an example apparatus 100.

In examples, such as the example illustrated in FIG. 9, the apparatus 100 comprises a printed circuit board 906 (PCB).

In some such examples, the example comprises one or more biasing magnets 908 provided adjacent to the PCB 906.

FIGS. 13A and 13B illustrate examples of an apparatus 100 according to example embodiments.

In the example of FIG. 13A, the resonant cavity 102 is positioned within a shielding box 130. In some, but not necessarily all, examples, the shielding box shields against microwaves. In some, but not necessarily all, examples, the shielding box does not shield against magnetic field. Therefore, the applied magnetic field reaches the material 110 (not illustrated) within the resonant cavity 102, and signal leakage from the apparatus 100 is inhibited. The shielding box 130 acts to improve reflections of electromagnetic signals, thus improving the readout when the means configured to couple an output electromagnetic signal from the resonant cavity is configured for measuring a reflected electromagnetic signal.

The shielding box 130 has a height H, a width W, and a depth D (not illustrated). The required height, width and depth of the shielding box 130 vary in dependence on the size of the resonant cavity and the wavelength of the input and output electromagnetic signals. For example, a shielding box 130 that is too small may cause changes to the electromagnetic field across the resonant cavity 102, and thus cause the resonant cavity 102 to leave the TE₀₁ mode.

In some, but not necessarily all, examples, the shielding box 130 is configured to enable an excitation means, positioned outside of the shielding box, to optically excite the material; for example, a gap may be provided on one face of the shielding box. In some, but not necessarily all, examples, the gap is provided on a top face of the shielding box, above the resonant cavity in use, and the optical excitation means is provided above the shielding box.

In some, but not necessarily all, examples, the height, width and depth are each twice the diameter of the resonant cavity; for example, for a resonant cavity having 2 cm diameter, the shielding box 130 has dimensions H4 cm×W4 cm×D4 cm.

The distance between the resonant cavity 102 and the means for coupling an input electromagnetic signal to the resonant cavity determines the achievable quality factor (Q) of the resonator.

In the example of FIG. 13A, the resonator is raised from a base of the shielding box by a spacer 132 having a height H(s). In some, but not necessarily all, examples, the spacer comprises quartz.

The spacer changes the distance between the resonant cavity 102 and the means for coupling an input electromagnetic signal to the resonant cavity 102.

FIG. 13B illustrates an example in which the means for coupling an input electromagnetic signal to the resonant cavity 102 is a microstrip 134, and the resonant cavity 102 and the microstrip 134 are provided on a printed circuit board (PCB) 136. In some, but not necessarily all, examples, the microstrip 134 also provides the means for coupling an output electromagnetic signal from the resonant cavity.

In some, but not necessarily all, examples, the microstrip 134 is positioned within the shielding box 130. In some, but not necessarily all, examples, the microstrip is positioned outside of the shielding box. In other examples, the microstrip is provided and no shielding box is provided.

In some, but not necessarily all, examples, the means for coupling an input electromagnetic signal to the resonant cavity 102 and/or the means for coupling an output electromagnetic signal from the resonant cavity 102 comprise one or more metallic ports 138. The metallic port(s) may be used as an alternative to the microstrip.

In some, but not necessarily all, examples, one metallic port 138 provides the means for coupling an input electromagnetic signal to the resonant cavity 102 and the means for coupling an output electromagnetic signal from the resonant cavity 102. In other examples, a first metallic port 138 provides the means for coupling an input electromagnetic signal 105 to the resonant cavity 102 and a second metallic port 138 provides the means for coupling an output electromagnetic signal 107 from the resonant cavity. References to the metallic port 138 herein should be considered to refer to examples using a single metallic port and examples using two or more metallic ports, unless explicitly stated otherwise.

In some, but not necessarily all, examples, the metallic port 138 extends through a wall of the shielding box 130 such that a first portion of the metallic port is provided within the shielding box and, optionally, a second portion of the metallic port is provided outside of the shielding box.

In some, but not necessarily all, examples, the metallic port 138 comprises a highly-conductive metal. In some, but not necessarily all, examples, the second portion of the metallic port is coated or surrounded with a dielectric insulating material such as Polytetrafluoroethylene (PTFE).

FIGS. 13C and 13D illustrate an example in which a first metallic port 138 provides the means for coupling an input electromagnetic signal 105 to the resonant cavity 102 and a second metallic port 138 provides the means for coupling an output electromagnetic signal 107 from the resonant cavity. As illustrated in FIGS. 13C and 13D, the first metallic port 138 and the second metallic port 138 are provided at opposite sides of the shielding box 130.

The horizontal distance between the microstrip 134 and the resonant cavity 102 is labelled X. The vertical distance between the microstrip 134 and the resonant cavity 102 is dependent on H(s). Therefore, the achievable quality factor Q of the resonator is dependent on X and H(s).

As an illustrative example, spin lifetime in diamond T2* is expected to be between 500 ns and 50 μs. A typical T2*=5 μs gives a linewidth of 1/T2*=200 kHz. This corresponds to a Q factor of 14,350 (Q=ω/κ_{DR}=2.87 GHz/200 kHz).

FIG. 14 illustrates an example apparatus 100 provided with an optical cavity for optical excitation and readout.

In the example of FIG. 14, the material 110 is provided within an optical cavity 140. The optical cavity 140 is provided within the resonant cavity 102.

In some, but not necessarily all, examples, the optical cavity 140 comprises two reflectors 142,144. The reflectors 142, 144 are positioned above and below the material 110. In some, but not necessarily all, examples, the reflectors 142, 144 are mirrors, for example distributed-feedback (DFB) mirrors, which usually comprise two different optical materials.

The arrangement of the optical cavity 140, such as the material of the reflectors 142, 144 and the position of the reflectors 142, 144 relative to the material 110, is dependent on the required excitation wavelength and luminescence.

For example, the optical cavity 140 may be arranged to enhance excitation having a wavelength of 532 nm from a material 110 such as diamond with nitrogen vacancy centers.

For example, the optical cavity 140 may be arranged to enhance luminescence having a wavelength of 637 nm and above from a material 110 such as diamond with nitrogen vacancy centers or diamond with silicon vacancy centers.

FIG. 15 illustrates an example apparatus 100 in which the excitation means 112 are integrated with the material 110 by being provided adjacent to the material 110.

In the example of FIG. 15, the excitation means 112 is a vertical-cavity surface-emitting laser (VCSEL), but it is to be appreciated that other excitation means 112 may be used.

In the example of FIG. 15, the excitation means 112 are positioned directly above the material 110. In other examples, the excitation means 112 are positioned directly below the material 110.

In an alternative example (not illustrated), the excitation means 112 and material 110 may be integrated by placing the material 110 within the excitation means 112, for example in a laser cavity.

In some, but not necessarily all, examples, the integrated excitation means 112 and material 110 may be provided within an optical cavity 140 such as the one illustrated in FIG. 14.

FIG. 16 illustrates an example apparatus comprising a flux concentrator 160.

The flux concentrator 160 is used to enhance the magnetic field strength at the material 110, which in turn provides enhanced sensitivity.

FIG. 16 schematically illustrates one possible flux concentrator. Other designs are also possible, for instance with optical access through the center of a hollow flux concentrator, or with an optical fiber.

The magnetic field enhancement factor is designed with parameters including base diameter, height and gap distance and tip distance. Enhancement factors of up to 2500 may be provided.

In some, but not necessarily all, examples, the magnetic flux concentrator 160 may comprise a high permeability, low power loss material, for example one or more of: ferrite; magneto-dielectric materials; cobalt-iron; silicon-iron; or nitrogen-iron. In some, but not necessarily all, examples, the material is selected in dependence on at least one of: target magnetic field intensity; sensitivity requirements; required measurement speeds; or other factors.

In some, but not necessarily all, examples, the magnetic flux concentrator 160 is provided in an apparatus 100 in combination with the integrated excitation means 112 and material 110 (as illustrated in FIG. 15) and/or an optical cavity 140 (such as illustrated in FIG. 15).

There is therefore provided an apparatus 100 for determining features of an electromagnetic input signal 105.

The apparatus 100 is therefore configured to perform method 1100.

Method 1100, illustrated in FIG. 10, comprises:
at block 1102, coupling an input electromagnetic signal into a resonant cavity;
at block 1104, applying a magnetic field to a material having at least one covalent structural defect within the resonant cavity;
at block 1106, (while applying the magnetic field) optically exciting the material;
while applying the magnetic field and optically exciting the material simultaneously:
at block 1108, controlling a variation in time of the applied magnetic field within the resonant cavity;
at block 1110, coupling an output signal from the resonant cavity; and
at block 1112, determining one or more features of the input electromagnetic signal based at least in part on a variation of the output signal with variation in time of the applied magnetic field.

FIG. 11 illustrates an example of a controller 1200 suitable for use in an apparatus 100. Implementation of a controller 1200 may be as controller circuitry. The controller 1200 may be implemented in hardware alone, have certain aspects in software including firmware alone or can be a combination of hardware and software (including firmware).

As illustrated in FIG. 11 the controller 1200 may be implemented using instructions that enable hardware functionality, for example, by using executable instructions of a computer program 1206 in a general-purpose or special-purpose processor 1202 that may be stored on a computer readable storage medium (disk, memory etc.) to be executed by such a processor 1202.

The processor 1202 is configured to read from and write to the memory 1204. The processor 1202 may also comprise an output interface via which data and/or commands are output by the processor 1202 and an input interface via which data and/or commands are input to the processor 1202.

The memory 1204 stores a computer program 1206 comprising computer program instructions (computer program code) that controls the operation of the apparatus 100 when loaded into the processor 1202. The computer program instructions, of the computer program 1206, provide the logic and routines that enables the apparatus to perform the methods illustrated in the accompanying Figs. The processor 1202 by reading the memory 1204 is able to load and execute the computer program 1206.

The apparatus 100 comprises:
at least one processor 1202; and
at least one memory 1204 including computer program code
the at least one memory 1204 and the computer program code configured to, with the at least one processor 1202, cause the apparatus 100 at least to perform:
coupling 1102 an input electromagnetic signal into a resonant cavity;
applying 1104 a magnetic field to a material having at least one covalent structural defect within the resonant cavity;
optically exciting 1106 the material;
controlling 1108 a variation in time of the applied magnetic field within the resonant cavity;
coupling 1110 an output signal from the resonant cavity; and
determining 1112 one or more features of the input electromagnetic signal based at least in part on a variation of the output signal with variation in time of the applied magnetic field.

The apparatus 100 comprises:
at least one processor 1202; and
at least one memory 1204 storing instructions that, when executed by the at least one processor 1202, cause the apparatus at least to:
couple 1102 an input electromagnetic signal into a resonant cavity;
apply 1104 a magnetic field to a material having at least one covalent structural defect within the resonant cavity;
optically excite 1106 the material;
control 1108 a variation in time of the applied magnetic field within the resonant cavity;
couple 1110 an output signal from the resonant cavity; and
determine 1112 one or more features of the input electromagnetic signal based at least in part on a variation of the output signal with variation in time of the applied magnetic field.

As illustrated in FIG. 12, the computer program 1206 may arrive at the apparatus 100 via any suitable delivery mechanism 1208. The delivery mechanism 1208 may be, for example, a machine readable medium, a computer-readable medium, a non-transitory computer-readable storage medium, a computer program product, a memory device, a record medium such as a Compact Disc Read-Only Memory (CD-ROM) or a Digital Versatile Disc (DVD) or a solid-state memory, an article of manufacture that comprises or tangibly embodies the computer program 1206. The delivery mechanism may be a signal configured to reliably transfer the computer program 1206. The apparatus 100 may propagate or transmit the computer program 1206 as a computer data signal.

Computer program instructions for causing an apparatus to perform at least the following or for performing at least the following:
coupling 1102 an input electromagnetic signal into a resonant cavity;
applying 1104 a magnetic field to a material having at least one covalent structural defect within the resonant cavity;
optically exciting 1106 the material;
controlling 1108 a variation in time of the applied magnetic field within the resonant cavity;
coupling 1110 an output signal from the resonant cavity; and
determining 1112 one or more features of the input electromagnetic signal based at least in part on a variation of the output signal with variation in time of the applied magnetic field.

The computer program instructions may be comprised in a computer program, a non-transitory computer readable medium, a computer program product, a machine readable medium. In some but not necessarily all examples, the computer program instructions may be distributed over more than one computer program.

Although the memory 1204 is illustrated as a single component/circuitry it may be implemented as one or more separate components/circuitry some or all of which may be integrated/removable and/or may provide permanent/semi-permanent/dynamic/cached storage.

Although the processor 1202 is illustrated as a single component/circuitry it may be implemented as one or more separate components/circuitry some or all of which may be integrated/removable. The processor 1202 may be a single core or multi-core processor.

References to ‘computer-readable storage medium’, ‘computer program product’, ‘tangibly embodied computer program’ etc. or a ‘controller’, ‘computer’, ‘processor’ etc. should be understood to encompass not only computers having different architectures such as single/multi-processor architectures and sequential (Von Neumann)/parallel architectures but also specialized circuits such as field-programmable gate arrays (FPGA), application specific circuits (ASIC), signal processing devices and other processing circuitry. References to computer program, instructions, code etc. should be understood to encompass software for a programmable processor or firmware such as, for example, the programmable content of a hardware device whether instructions for a processor, or configuration settings for a fixed-function device, gate array or programmable logic device etc.

As used in this application, the term ‘circuitry’ may refer to one or more or all of the following:
(a) hardware-only circuitry implementations (such as implementations in only analog and/or digital circuitry) and
(b) combinations of hardware circuits and software, such as (as applicable):
(i) a combination of analog and/or digital hardware circuit(s) with software/firmware and
(ii) any portions of hardware processor(s) with software (including digital signal processor(s)), software, and memory or memories that work together to cause an apparatus, such as a mobile phone or server, to perform various functions and
(c) hardware circuit(s) and or processor(s), such as a microprocessor(s) or a portion of a microprocessor(s), that requires software (for example, firmware) for operation, but the software may not be present when it is not needed for operation.

This definition of circuitry applies to all uses of this term in this application, including in any claims. As a further example, as used in this application, the term circuitry also covers an implementation of merely a hardware circuit or processor and its (or their) accompanying software and/or firmware. The term circuitry also covers, for example and if applicable to the particular claim element, a baseband integrated circuit for a mobile device or a similar integrated circuit in a server, a cellular network device, or other computing or network device.

The blocks illustrated in the accompanying Figs may represent steps in a method and/or sections of code in the computer program 1206. The illustration of a particular order to the blocks does not necessarily imply that there is a required or preferred order for the blocks and the order and arrangement of the block may be varied. Furthermore, it may be possible for some blocks to be omitted.

Where a structural feature has been described, it may be replaced by means for performing one or more of the functions of the structural feature whether that function or those functions are explicitly or implicitly described.

The above-described examples find application as enabling components of: automotive systems; telecommunication systems; electronic systems including consumer electronic products; distributed computing systems; media systems for generating or rendering media content including audio, visual and audio visual content and mixed, mediated, virtual and/or augmented reality; personal systems including personal health systems or personal fitness systems; navigation systems; user interfaces also known as human machine interfaces; networks including cellular, non-cellular, and optical networks; ad-hoc networks; the internet; the internet of things; virtualized networks; and related software and services.

The apparatus can be provided in an electronic device, for example, a mobile terminal, according to an example of the present disclosure. It should be understood, however, that a mobile terminal is merely illustrative of an electronic device that would benefit from examples of implementations of the present disclosure and, therefore, should not be taken to limit the scope of the present disclosure to the same. While in certain implementation examples, the apparatus can be provided in a mobile terminal, other types of electronic devices, such as, but not limited to: mobile communication devices, hand portable electronic devices, wearable computing devices, portable digital assistants (PDAs), pagers, mobile computers, desktop computers, televisions, gaming devices, laptop computers, cameras, video recorders, GPS devices and other types of electronic systems, can readily employ examples of the present disclosure. Furthermore, devices can readily employ examples of the present disclosure regardless of their intent to provide mobility.

The term ‘comprise’ is used in this document with an inclusive not an exclusive meaning. That is any reference to X comprising Y indicates that X may comprise only one Y or may comprise more than one Y. If it is intended to use ‘comprise’ with an exclusive meaning then it will be made clear in the context by referring to “comprising only one . . . ” or by using “consisting”.

In this description, the wording ‘connect’, ‘couple’ and ‘communication’ and their derivatives mean operationally connected/coupled/in communication. It should be appreciated that any number or combination of intervening components can exist (including no intervening components), i.e., so as to provide direct or indirect connection/coupling/communication. Any such intervening components can include hardware and/or software components.

As used herein, the term “determine/determining” (and grammatical variants thereof) can include, not least: calculating, computing, processing, deriving, measuring, investigating, identifying, looking up (for example, looking up in a table, a database or another data structure), ascertaining and the like. Also, “determining” can include receiving (for example, receiving information), accessing (for example, accessing data in a memory), obtaining and the like. Also, “determine/determining” can include resolving, selecting, choosing, establishing, and the like.

In this description, reference has been made to various examples. The description of features or functions in relation to an example indicates that those features or functions are present in that example. The use of the term ‘example’ or ‘for example’ or ‘can’ or ‘may’ in the text denotes, whether explicitly stated or not, that such features or functions are present in at least the described example, whether described as an example or not, and that they can be, but are not necessarily, present in some of or all other examples. Thus ‘example’, ‘for example’, ‘can’ or ‘may’ refers to a particular instance in a class of examples. A property of the instance can be a property of only that instance or a property of the class or a property of a sub-class of the class that includes some but not all of the instances in the class. It is therefore implicitly disclosed that a feature described with reference to one example but not with reference to another example, can where possible be used in that other example as part of a working combination but does not necessarily have to be used in that other example.

Although examples have been described in the preceding paragraphs with reference to various examples, it should be appreciated that modifications to the examples given can be made without departing from the scope of the claims.

Features described in the preceding description may be used in combinations other than the combinations explicitly described above.

Although functions have been described with reference to certain features, those functions may be performable by other features whether described or not.

Although features have been described with reference to certain examples, those features may also be present in other examples whether described or not.

The term ‘a’, ‘an’ or ‘the’ is used in this document with an inclusive not an exclusive meaning. That is any reference to X comprising a/an/the Y indicates that X may comprise only one Y or may comprise more than one Y unless the context clearly indicates the contrary. If it is intended to use ‘a’, ‘an’ or ‘the’ with an exclusive meaning then it will be made clear in the context. In some circumstances the use of ‘at least one’ or ‘one or more’ may be used to emphasis an inclusive meaning but the absence of these terms should not be taken to infer any exclusive meaning.

The presence of a feature (or combination of features) in a claim is a reference to that feature or (combination of features) itself and also to features that achieve substantially the same technical effect (equivalent features). The equivalent features include, for example, features that are variants and achieve substantially the same result in substantially the same way. The equivalent features include, for example, features that perform substantially the same function, in substantially the same way to achieve substantially the same result.

In this description, reference has been made to various examples using adjectives or adjectival phrases to describe characteristics of the examples. Such a description of a characteristic in relation to an example indicates that the characteristic is present in some examples exactly as described and is present in other examples substantially as described.

The above description describes some examples of the present disclosure however those of ordinary skill in the art will be aware of possible alternative structures and method features which offer equivalent functionality to the specific examples of such structures and features described herein above and which for the sake of brevity and clarity have been omitted from the above description. Nonetheless, the above description should be read as implicitly including reference to such alternative structures and method features which provide equivalent functionality unless such alternative structures or method features are explicitly excluded in the above description of the examples of the present disclosure.

Whilst endeavoring in the foregoing specification to draw attention to those features believed to be of importance it should be understood that the Applicant may seek protection via the claims in respect of any patentable feature or combination of features hereinbefore referred to and/or shown in the drawings whether or not emphasis has been placed thereon.

1. An apparatus comprising:
a resonant cavity configured for optical excitation of a material to which a magnetic field is applied, the material having at least one covalent structural defect;
an electromagnetic feed configured to couple an input electromagnetic signal into the resonant cavity;
an electromagnetic feed configured to couple an output electromagnetic signal from the resonant cavity;
at least one processor; and
at least one memory storing instructions that, when executed by the at least one processor, cause the apparatus at least to perform: controlling a variation in time of the applied magnetic field within the resonant cavity, and determine one or more features of the input electromagnetic signal based at least in part on a variation of the output electromagnetic signal with variation in time of the applied magnetic field.

2. An apparatus as claimed in claim 1, wherein the output electromagnetic signal has a frequency outside the range of visible light/does not comprise visible light.

3. An apparatus as claimed in claim 1, wherein the output electromagnetic signal is a microwave signal.

4. An apparatus as claimed in claim 1, wherein the resonant cavity comprises a dielectric material.

5. An apparatus as claimed in claim 1, comprising at least one of: the material; or an optical excitation means for exciting the material; and wherein the instructions, when executed by the at least one processor, further cause the apparatus to perform application of the applied magnetic field within the resonant cavity.

6. An apparatus as claimed in claim 1, wherein the instructions, when executed by the at least one processor, further cause the apparatus to perform coupling an output signal from the resonant cavity, wherein coupling the output signal from the resonant cavity comprises detecting light emitted by the material.

7. An apparatus as claimed in claim 1, wherein controlling a variation in time of the applied magnetic field within the resonant cavity comprises varying an applied magnetic flux density (B) in time.

8. An apparatus as claimed in claim 6, wherein controlling a variation in time of the applied magnetic field within the resonant cavity comprises varying a magnetic flux density (B) of a uniform applied magnetic field in time.

9. An apparatus as claimed in claim 1, wherein coupling an output electromagnetic signal from the resonant cavity comprises at least one of: measuring a transmitted electromagnetic signal; or measuring a reflected electromagnetic signal.

10. An apparatus as claimed in claim 1, wherein the instructions, when executed by the at least one processor, further cause the apparatus to perform controlling a frequency of the input electromagnetic signal before coupling into the resonant cavity.

11. An apparatus as claimed in claim 1, wherein the instructions, when executed by the at least one processor, further cause the apparatus to perform:
controlling a frequency of a reference signal; and
controlling a frequency of the input electromagnetic signal by mixing the input electromagnetic signal with the reference signal before coupling the input electromagnetic signal into the resonant cavity; or
wherein controlling a frequency of the input electromagnetic signal comprises producing the input electromagnetic signal as a pulse before coupling the pulsed input electromagnetic signal into the resonant cavity; or
wherein the instructions, when executed by the at least one processor, further cause the apparatus to perform:
detecting a signal; and
mixing the detected signal with the reference signal.

12. An apparatus as claimed in claim 1, wherein determining one or more features of the input electromagnetic signal comprises determining at least an amplitude of the input electromagnetic signal based on a change in amplitude of the output electromagnetic signal with variation in time of the applied magnetic field.

13. An apparatus as claimed in claim 1, wherein determining one or more features of the input electromagnetic signal comprises determining that resonance occurs based on the variation of the output electromagnetic signal and determining at least a frequency of the input electromagnetic signal based on the applied magnetic field when resonance occurs.

14. An apparatus as claimed in claim 1, wherein determining one or more features of the input electromagnetic signal comprises determining at least an amplitude of the input electromagnetic signal based on a change in phase of the output electromagnetic signal with variation in time of the applied magnetic field.

15. An apparatus as claimed in claim 1, wherein the instructions, when executed by the at least one processor, further cause the apparatus to perform:
determining one or more features of the applied magnetic field, based at least in part on the output electromagnetic signal or
determining one or more features of the applied magnetic field and detecting changes in the output electromagnetic signal based on a variation of a frequency of the input electromagnetic signal.

16. An apparatus as claimed in claim 1, wherein the resonant cavity is positioned within a shielding box, wherein the shielding box is configured to shield against microwaves and is not configured to shield against magnetic field.

17. An apparatus as claimed in claim 1, wherein a distance between the resonant cavity and the electromagnetic feed comprises a vertical component and a horizontal component, wherein the vertical component is dependent on a height of a spacer on which the resonator is positioned.

18. An apparatus as claimed in claim 5, wherein the optical excitation means comprise a laser or light emitting diode, LED, wherein the optical excitation means are configured to output light with a wavelength below or equal to 532 nm.

19. An apparatus as claimed in claim 1, wherein the material comprises nitrogen vacancy center diamond.

20. A method comprising:
coupling an input electromagnetic signal into a resonant cavity;
applying a magnetic field to a material having at least one covalent structural defect within the resonant cavity;
optically exciting the material;
controlling a variation in time of the applied magnetic field within the resonant cavity;
coupling an output electromagnetic signal from the resonant cavity by an electromagnetic feed; and
determining one or more features of the input electromagnetic signal based at least in part on a variation of the output electromagnetic signal with variation in time of the applied magnetic field.
